(19) United States
(12) Patent Application Publication
(10) Pub. No.: US 2010/0027569 A1
(43) Pub. Date: Feb. 4, 2010

(54) UV DIODE-LASER MODULE WITH OPTICAL FIBER DELIVERY

(76) Inventors: John Brekke, Cool, CA (US); David Frank Furmidge, Granite Bay, CA (US)

Correspondence Address: Coherent, Inc. c/o Morrison & Forester, 425 Market Street, San Francisco, CA, 94105-2482, US

(21) Appl. No.: 12/181,548

(22) Filed: Jul. 29, 2008

(51) Int. Cl. H01S 3/30; H01S 5/00

(52) U.S. Cl. 372/5; 372/50.23

(57) ABSTRACT

A diode-laser module includes a diode-laser delivering radiation having a wavelength less than 450 nm and located a housing. Focusing optics focus the radiation into a single-mode optical fiber located in the housing. The radiation is focused through an end-cap bonded to the single-mode fiber and having a diameter greater than the core-diameter of the single-mode fiber. The length of the end-cap is selected cooperative with the focusing optics such that the beam intensity at the entrance end of the end-cap is below a level that would cause photodecomposition of any gaseous hydrocarbons in the housing.

### TECHNICAL FIELD OF THE INVENTION

The present invention relates in general to coupling the output of diode-laser into an optical fiber. The invention relates in particular to coupling ultraviolet (UV) radiation from a diode-laser into an optical fiber.

### DISCUSSION OF BACKGROUND ART

There are certain applications of laser radiation that require radiation including a plurality of discrete wavelengths or colors. Such applications include flow cytometry, genomics, and confocal microscopy. As commercial lasers typically emit radiation at nominally only one wavelength, such a multicolor beam is typically provided by combining the beams of a plurality of lasers using an optical system including a plurality of dichroic-filter-coated beam combiners. As these applications require relatively low power radiation, for example less than about 1 Watt (W), each color can be conveniently supplied by the output of a single-diode laser. The diode-laser is usually accommodated in a laser head or module. The module usually includes collimating optics for shaping and collimating an output beam, and connections for electrical power, modulation electronics or control electronics. Modules are commercially available with wavelengths (colors) ranging from about 375 nanometers (nm) to about 785 nm.

It is often preferred in such modules or laser-heads that the diode-laser output radiation is coupled (focused) into an optical fiber for delivery to a location where the radiation will be used. The optical fiber may be terminated by a collimating lens, or terminated by a fiber coupler for connection to apparatus requiring the radiation. It has been found, however, that for such modules delivering radiation at wavelengths less than about 450 nm, output power, at a constant drive current, can drop about 100 times more rapidly with “on” time than for modules delivering radiation at longer wavelengths. This is a somewhat surprising finding, as in each case, the intensity of the focused output radiation is between about 500 and 1000 times less than would be expected to cause optical damage to the fiber core.

One way to compensate for a progressive drop in power is to under-specify the output power of the module to a value significantly less than the “fresh” maximum available from the diode-laser, and gradually increase drive current over the life of the module to maintain the “under-specified” power. This approach, however, typically results in poor beam quality and excessive scatter. It would be preferable, however, to find and eliminate the root cause of the relatively rapid power-decline such that the same fiber-coupled UV diode-laser module could deliver a power close to the maximum available, over a lifetime comparable to that of longer wavelength modules.

### SUMMARY OF THE INVENTION

In one aspect, apparatus in accordance with the present invention comprises a housing having a diode-laser located therein. The diode-laser is arranged to deliver a beam of radiation having a wavelength less than about 450 nanometers. A few-mode optical fiber has a proximal end thereof located in the housing. The few-mode optical fiber has a few-mode core surrounded by a cladding. An end-cap of a material transparent to the wavelength of the diode-laser radiation has a proximal end and a distal end. The distal end of the end-cap is bonded to the proximal end of the optical fiber. An optical arrangement located in the housing is arranged to focus radiation delivered by the diode-laser through the proximal end of the end-cap into the core of the few-mode optical fiber. The focused beam has a greater cross-section area at the proximal end of the fiber than at the distal end of the fiber.

In one preferred embodiment of the apparatus, the end-cap is a relatively short length of multi-mode optical fiber, having a cladding diameter equal to the cladding diameter of the single mode fiber. The length of the multi-mode optical fiber is about 5 times the cladding diameter or less.

### BRIEF DESCRIPTION OF THE DRAWINGS

The accompanying drawings, which are incorporated in and constitute a part of the specification, schematically illustrate a preferred embodiment of the present invention, and together with the general description given above and the detailed description of the preferred embodiment given below, serve to explain principles of the present invention.

FIG. 1 is a three-dimensional view of a fiber-pigtailed diode-laser module in accordance with the present invention including a housing in which a diode-laser (not shown) is housed and an optical fiber for delivering radiation from the diode-laser from the housing.

FIG. 2 schematically illustrates a diode-laser within the housing of FIG. 1, a proximal end of the optical fiber of FIG. 1 within the housing, the proximal end of the optical fiber having an end-cap bonded thereto, and an optical arrangement for focusing radiation emitted by the diode-laser through the end-cap and into the optical fiber.

FIG. 3 schematically illustrates details of one preferred embodiment of the end-cap and optical fiber of FIG. 2.

### DETAILED DESCRIPTION OF THE INVENTION

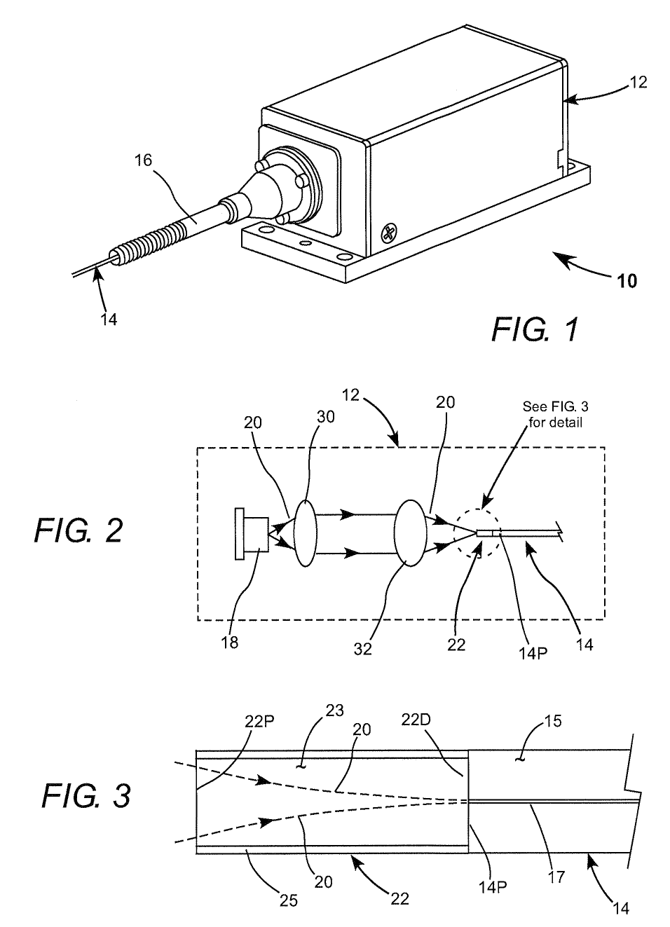

Referring now to the drawings, wherein like components are designated by like reference numerals, FIG. 1 is a three-dimensional view of a fiber-pigtailed diode-laser module 10 in accordance with the present invention. Module 10 includes a housing 12 in which a diode-laser (not shown) is housed. An optical fiber 14 is provided for delivering radiation from the diode-laser from the housing. Optical fiber 14 is protected by a reinforced polymer sheath 16.

Module 10 can have a length of about four inches and a height and width of about 1.5 inches. These dimensions, however, should not be construed as limiting the present invention to a module of any particular size.

FIG. 2 and FIG. 3 schematically illustrate details of an optical layout inside housing 12 of FIG. 1. In FIG. 2, housing 12 is depicted in phantom. Located in housing 12 is a current-driven diode-laser package 18 arranged to deliver radiation having a wavelength of about 450 nm or less. Such a diode-laser package is commercially available from Nichia Corporation, of Japan. The diode-laser output may be continuous wave (CW) or amplitude modulated depending on whether drive current is CW or amplitude modulated. Electrical connections to the diode laser are not shown for simplicity of illustration. The output-power of such a diode-laser package is typically less than about 200 milliwatts (mW). The term output power here means peak output-power. In the case of CW radiation, the peak power will be about equal to the short-term time-averaged power. In the case of amplitude modulated radiation the short term time-averaged power will be less than the peak power.

Optical fiber 14, in this example extends into housing 12 to receive radiation from diode-laser 18. Optical fiber 14 has a core 17 surrounded by a cladding 15. An end-cap 22 is bonded to proximal end 14P of optical fiber 14. Bonding is preferably made by thermally fusing the end cap to the fiber. Optical fiber 14 is a few-mode optical fiber. A few-mode optical fiber, as understood by those skilled in the art to which the present invention pertains, is an optical fiber in which the core has a diameter only sufficient to transport radiation having a particular wavelength in up to about 4 modes. Such a fiber is often referred to by practitioners of the art as a single-mode fiber although depending on the wavelength more than one-mode may be supported. Typically a few-mode optical fiber has a core diameter less than about 5 micrometers (μm). Typically, the cladding has a diameter about twenty or more-times the diameter of the core. In one preferred configuration, optical fiber 14 has a core diameter of 3.5 μm and a cladding (outside) diameter of 125 μm.

FIG. 3 depicts end-cap 22 as a relatively short length of multi-mode optical fiber having a core 23 surrounded by a cladding 25. Distal end 22D of the multi-mode optical fiber is bonded to proximal end 14P of optical fiber 14 as noted above. In one preferred configuration, end-cap 22 is a multimode optical fiber having a core diameter of 105.0 μm and a cladding (outside) diameter of 125 μm.

The use of multimode optical fiber, here, is simply for convenience, as such optical fiber is readily commercially available. End-cap 22 may also be a cylindrical piece of material transparent to the diode-laser radiation, for example a piece of fused-silica (SiO₂).

Diode-laser package 18 delivers radiation as an elliptical beam 20 having a divergence of 8-22 degrees. Beam 20 is collimated by a lens 30. One suitable collimating lens is available as part number L671-ZX from Archer OpTx Inc. of Rowlett, Tex. This lens has a focal length of 4.0 millimeters (mm) and a numerical aperture of 0.6. A typical diameter of the collimated beam is about 1.3 mm. Collimated beam 20 is focused (brought to a beam waist) by a lens 32 through end-cap 22 via proximal end 22P thereof into core 17 of optical fiber 14. The focused beam has a greater cross-section area at the proximal end of the fiber than at the distal end of the fiber.

The diameter of the beam at the focus (beam waist) should be matched to the mode field diameter (MFD) of core 17. For a core diameter of 3.5 μm exemplified above a typical MFD is about 3.0 μm. One suitable collimating lens is available as part number 170-A from Archer OpTx Inc. This lens has a focal length of 6.1 mm and a numerical aperture of 0.6. In an example where such a lens is used to focus a beam having a diameter of about 1.3 mm, a preferred length for end-cap 22 is preferably between about 250 μm and 500 μm. In general, the length of end-cap 22 is preferably less than about 1.0 mm.

In the description provided above it is assumed that optical fiber 14 has one end thereof located in housing 12 and an opposite end located outside the housing. Those skilled in the art will recognize that principles of the present invention are equally applicable if optical fiber 14 is located inside the housing and connected to a fiber-connector on the housing. In this case, another optical fiber could be connected to the connector for transporting radiation from optical fiber 14 to a location or at which the radiation is required.

In an experimental evaluation of the effectiveness of apparatus 10, laser radiation output by diode-laser 18 had a wavelength of 405 nm. The radiation was focused into optical fiber 17 without end-cap 22 attached thereto. Power was measured at an output end of optical fiber 14. The power dropped 1½% per day until the laser provided negligible energy. With end-cap 22 attached to fiber 14, no significant drop in power was observed over 2000 hours of testing. In this experimental evaluation the diameter of beam 20 at proximal end 22P of end-cap 22 was about 20 times the diameter of the beam at proximal end 14P of fiber 14, i.e., the beam-waist or focal-spot diameter. It is believed that diameter of the beam at the proximal end of the end cap should be at least ten times greater (and preferably twenty times greater) than the diameter of the beam at the proximal end of the fiber 14.

It is believed without being limited to a particular theory that a reason for the rapid power drop-off in the absence of end-cap 22 is that the intensity of radiation in focused beam 20, while not sufficient to cause actual optical damage, is sufficient at wavelengths less than 450 nm to cause photodecomposition of any hydrocarbon gases in housing 12. Such hydrocarbon gases can result, for example, from sealants or cleaning solutions used in or in the assembly of the housing and optical elements therein. Photodecomposition of such hydrocarbons can result in the deposition of carbon-rich solid contaminants on optical fiber 14. Such carbon rich material can absorb radiation resulting in a progressive loss of power. The absorption of the radiation can also precipitate actual optical damage to the fiber at intensity less that would be required on a contaminant-free surface, thereby accelerating loss of power. The approach disclosed herein is intended to reduce the a real intensity of the beam at the entrance end of the end-cap is below a level that would cause photodecomposition of any gaseous hydrocarbons in the housing.

The present invention is described above in terms of a preferred and other embodiments. The invention is not limited, however, to the embodiments described and depicted. Rather, the invention is limited only by the claims appended hereto.

What is claimed is:

1. Optical apparatus, comprising:
a housing;
a diode-laser located in the housing and arranged to deliver a beam of radiation having a wavelength less than about 450 nanometers;
a few-mode optical fiber having a proximal end located in the housing, the few-mode optical fiber having a few-mode core surrounded by a cladding;
an end-cap of a material transparent to the wavelength of the diode-laser radiation, the end-cap having a proximal end and a distal end, the distal end of the end-cap being bonded to the proximal end of the optical fiber; and
an optical arrangement for focusing the beam of radiation delivered by the diode-laser through the proximal end of the end-cap into the core of the few-mode optical fiber with the focused beam having a greater cross-section area at the proximal end of the fiber than at the distal end of the fiber.

2. The apparatus of claim 1, wherein the end-cap is cylindrical and has a diameter greater than the diameter of the core of the few-mode optical fiber.

3. The apparatus of claim 2, wherein the end-cap is a relatively-short length of multi-mode optical fiber having a multi-mode core surrounded by a cladding.

4. The apparatus of claim 3, wherein the cladding diameter of the few-mode fiber is about the same as the cladding diameter of the multi-mode fiber.

5. The apparatus of claim 4, wherein the cladding diameter of the few-mode and multi-mode optical fibers is about 125 micrometers, the core diameter of the few-mode optical fiber is about 3.5 micrometers, and the core diameter of the multi-mode optical fiber is about 105 micrometers.

6. The apparatus of claim 5, wherein the multi-mode optical fiber has a length between about 250 micrometers and 500 micrometers.

7. The apparatus of claim 1, wherein the beam focused by the optical arrangement is about circular in cross-section and has a cross-section diameter at the proximal end of the end-cap at least about 20 times greater than the cross-section diameter at the proximal end of the few-mode optical fiber.

8. A laser diode package comprising:
a housing;
a laser diode mounted within the housing and having a face from which a beam of radiation is emitted;
a transport fiber having an input face located within the housing, said transport fiber having a few mode core and an outer cladding;
an end cap fused to the input end of the transport fiber, said end cap having a diameter about equal to the diameter of the transport fiber, with an input face of the end cap being spaced from the emitting face of the laser diode;
focusing optics for focusing light emitted from the laser diode into the input face of the end cap, said focusing optics configured to provide a focal diameter at the input face of the transport fiber that matches the mode fill diameter of the core and wherein the focusing optics and length of the end cap are configured so that the diameter of the laser beam at the input face of the end cap is at least ten times greater than the focal diameter at the input face of the transport fiber.

9. A package as recited in claim 8, wherein the diameter of the laser beam entering the input face of the end cap is at least twenty times greater than the focal diameter at the input face of the transport fiber.

10. A package as recited in claim 8, wherein the end cap includes a multimode core surrounding by a cladding layer.

11. A package as recited in claim 8, wherein laser diode generates radiation having a wavelength less than about 450 nanometers.
